(19) United States
(12) Patent Application Publication
(10) Pub. No.: US 2011/0254632 A1
(43) Pub. Date: Oct. 20, 2011

(54) PLL FREQUENCY SYNTHESIZER

(75) Inventor: Akihiro SAWADA, Osaka (JP)

(73) Assignee: PANASONIC CORPORATION, Osaka (JP)

(21) Appl. No.: 13/170,599

(22) Filed: Jun. 28, 2011

Related U.S. Application Data
(63) Continuation of application No. PCT/JP2010/001738, filed on Mar. 11, 2010.

(30) Foreign Application Priority Data
Jun. 23, 2009 (JP) 2009-148810

(51) Int. Cl. H03L 7/00

(52) U.S. Cl. 331/10

(57) ABSTRACT

A voltage-controlled oscillator (VCO) includes an inductor, a fine-adjustment capacitor, and a coarse-adjustment capacitor, and generates an oscillation clock. A frequency divider divides the frequency of the oscillation clock to generate a divided clock. A direct current (DC) voltage supply circuit supplies a DC voltage to a control node, and changes a voltage value of the DC voltage according to a DC value of an oscillation voltage in a coarse-adjustment mode. A frequency-band selection circuit switches a capacitance value of the coarse-adjustment capacitor based on a frequency difference between a reference clock and the divided clock so that an oscillation frequency band of the VCO is set to an oscillation frequency band corresponding to a target frequency in the coarse-adjustment mode. An oscillation control circuit increases or decreases a control voltage according to a phase difference between the reference clock and the divided clock in the fine-adjustment mode.

### CROSS-REFERENCE TO RELATED APPLICATION

This is a continuation of PCT International Application PCT/JP2010/001738 filed on Mar. 11, 2010, which claims priority to Japanese Patent Application No. 2009-148810 filed on Jun. 23, 2009. The disclosures of these applications including the specifications, the drawings, and the claims are hereby incorporated by reference in its entirety.

### BACKGROUND

The technology disclosed in this specification relates to PLL frequency synthesizers, and more particularly to technology to reduce variation in characteristics of PLL frequency synthesizers.

Conventionally, PLL frequency synthesizers, in which oscillation frequencies can be arbitrarily set, have been used in various technical fields. For example, in the field of wireless communication, PLL frequency synthesizers are used to generate local signals necessary for transmitting and receiving radio waves. As an example, Japanese Patent Application No. 2001-339301 describes a PLL frequency synthesizer which includes a voltage-controlled oscillator (VCO) having an inductor and a capacitor. The VCO includes an inductor, a variable capacitor whose capacitance value varies according to a voltage difference across the both ends, a plurality of switches, a plurality of capacitors respectively coupled in series to the plurality of switches, etc. In this PLL frequency synthesizer, first, an arbitrary control voltage is applied to one end of the variable capacitor, and on-off operations of the plurality of switches are controlled based on a frequency difference between a reference clock and a divided clock. This defines the oscillation frequency band of the VCO. Next, the control voltage applied to the one end of the variable capacitor is controlled according to a phase difference between the reference clock and the divided clock. A change of the control voltage causes a change in the capacitance value of the variable capacitor, and as a result, the oscillation frequency of the oscillation clock output from the VCO changes. Thus, the oscillation frequency of the oscillation clock is controlled.

### SUMMARY

However, the capacitance value of the variable capacitor varies nonlinearly according to a voltage difference across the both ends of the variable capacitor; therefore, the VCO gain (the amount of change of an oscillation frequency per unit voltage change of a control voltage) of the VCO is not a constant value. In addition, if the direct current (DC) value of the voltage at the other end of the variable capacitor varies due to manufacturing variation, supply voltage variation, temperature change, etc., the f-V characteristic (relationship between the control voltage and the oscillation frequency) of the VCO varies, and thus the VCO gain of the VCO also varies. This makes it difficult to reduce variation in characteristics (e.g., variation in a loop time constant) of PLL frequency synthesizers.

For example, if the DC value of the voltage at the other end of the variable capacitor increases, then as shown in FIG. 14, an f-V characteristic curve illustrating the f-V characteristic (relationship between a control voltage VT and an oscillation frequency fvco) of the VCO shifts to the right (direction along which the control voltage VT increases), and a gain characteristic curve illustrating the VCO gain Kvco of the VCO also shifts to the right. Therefore, after the oscillation frequency band of the VCO is set to one of oscillation frequency bands B0, B1, B2, and B3, the control voltage VT varies over a broader range of voltage values V91-VH9 rather than a range of voltage values VL9-VH9. In such a case, the VCO gain Kvco varies over a broader range of gain values K91-KH9 rather than a range of gain values KL9-KH9. Meanwhile, if the DC value of the voltage at the other end of the variable capacitor decreases, then as shown in FIG. 15, an f-V characteristic curve shifts to the left (direction along which the control voltage VT decreases), and a gain characteristic curve also shifts to the left. Therefore, the control voltage VT varies over a broader range of voltage values V92-VH9 rather than the range of voltage values VL9-VH9, and the VCO gain Kvco varies over a broader range of gain values K92-KH9 rather than the range of gain values KL9-KH9.

Thus, it is an object of the technology disclosed in this specification to provide a PLL frequency synthesizer in which variation in the gain characteristic of the VCO can be reduced.

According to one aspect of the present invention, a PLL frequency synthesizer is a PLL frequency synthesizer having a coarse-adjustment mode and a fine-adjustment mode, and includes a voltage-controlled oscillator (VCO), having an inductor, a fine-adjustment capacitor, coupled between a control node and an oscillation node, whose capacitance value is continuously variable according to a voltage difference between the control node and the oscillation node, and a coarse-adjustment capacitor whose capacitance value can be switched in a stepwise fashion, the VCO being configured to generate an oscillation clock having an oscillation frequency depending on an inductance value of the inductor and on capacitance values of the fine-adjustment capacitor and the coarse-adjustment capacitor, a frequency divider configured to divide the frequency of the oscillation clock to generate a divided clock, a direct current (DC) voltage supply circuit configured to, in the coarse-adjustment mode, supply a DC voltage to the control node and change a voltage value of the DC voltage according to a DC value of an oscillation voltage at the oscillation node, and in the fine-adjustment mode, stop supplying the DC voltage, a frequency-band selection circuit configured to, in the coarse-adjustment mode, switch the capacitance value of the coarse-adjustment capacitor based on a frequency difference between a reference clock and the divided clock so that an oscillation frequency band of the VCO is set to an oscillation frequency band corresponding to a target frequency determined by a frequency of the reference clock and a division ratio of the frequency divider, and an oscillation control circuit configured to, in the fine-adjustment mode, increase or decrease a control voltage at the control node according to a phase difference between the reference clock and the divided clock. This configuration allows variation in the gain characteristic of the VCO to be reduced, thereby allows variation in characteristics of the PLL frequency synthesizer to be reduced.

The fine-adjustment capacitor may have a capacitance characteristic such that as a differential voltage obtained by subtracting the control voltage from the oscillation voltage increases, the capacitance value increases; and the DC voltage supply circuit may, if the DC value of the oscillation voltage is higher than a predetermined reference value, increase the voltage value of the DC voltage according to a difference between the DC value of the oscillation voltage and the reference value, and if the DC value of the oscillation voltage is lower than the reference value, decrease the voltage value of the DC voltage according to the difference between the DC value of the oscillation voltage and the reference value.

Alternatively, the fine-adjustment capacitor may have a capacitance characteristic such that as a differential voltage obtained by subtracting the oscillation voltage from the control voltage increases, the capacitance value increases; and the DC voltage supply circuit may, if the DC value of the oscillation voltage is higher than a predetermined reference value, decrease the voltage value of the DC voltage according to a difference between the DC value of the oscillation voltage and the reference value, and if the DC value of the oscillation voltage is lower than the reference value, increase the voltage value of the DC voltage according to the difference between the DC value of the oscillation voltage and the reference value.

Furthermore, the PLL frequency synthesizer may further include a monitor circuit having a same configuration as that of the VCO, and the DC voltage supply circuit may receive a monitor voltage generated at an oscillation node of the monitor circuit, and change the voltage value of the DC voltage according to a DC value of the monitor voltage. This configuration prevents noise from being added to the oscillation clock.

Alternatively, the PLL frequency synthesizer may further include a monitor circuit configured to produce a similar voltage characteristic to that at the oscillation node of the VCO, and to generate a monitor voltage corresponding to the DC value of the oscillation voltage based on the voltage characteristic, and the DC voltage supply circuit may receive a monitor voltage generated by the monitor circuit, and change the voltage value of the DC voltage according to the monitor voltage. This configuration prevents noise from being added to the oscillation clock, and at the same time, reduces the circuit area of the monitor circuit.

### BRIEF DESCRIPTION OF THE DRAWINGS

FIG. 1 is a diagram illustrating an example configuration of a PLL frequency synthesizer according to the first embodiment.

FIG. 2 is a diagram illustrating an example configuration of the DC voltage supply circuit shown in FIG. 1.

FIG. 3 is a graph for explaining a basic operation of the PLL frequency synthesizer shown in FIG. 1.

FIG. 4 is a graph for explaining the f-V characteristic and the gain characteristic of the VCO respectively, when the DC value of the oscillation voltages is higher than a reference value.

FIG. 5 is a graph for explaining the f-V characteristic and the gain characteristic of the VCO respectively, when the DC value of the oscillation voltages is lower than a reference value.

FIG. 6 is a diagram for explaining a variation of the DC voltage supply circuit shown in FIG. 1.

FIG. 7 is a diagram for explaining a variation of the voltage generation section.

FIG. 8 is a diagram illustrating an example configuration of a PLL frequency synthesizer according to the second embodiment.

FIG. 9 is a diagram for explaining a variation of the monitor circuit and the DC voltage supply circuit shown in FIG. 8.

FIG. 10 is a diagram illustrating an example configuration of a PLL frequency synthesizer according to the third embodiment.

FIG. 11 is a diagram illustrating an example configuration of the DC voltage supply circuit shown in FIG. 10.

FIG. 12 is a graph for explaining the f-V characteristic and the gain characteristic of the VCO respectively, when the DC value of the oscillation voltages is higher than a reference value.

FIG. 13 is a graph for explaining the f-V characteristic and the gain characteristic of the VCO respectively, when the DC value of the oscillation voltages is lower than a reference value.

FIG. 14 is a graph for explaining a situation where the DC value of the voltage at the other end of a variable capacitor has increased.

FIG. 15 is a graph for explaining a situation where the DC value of the voltage at the other end of a variable capacitor has decreased.

### DETAILED DESCRIPTION

Example embodiments of the present invention will be described below in detail with reference to the drawings, in which like reference characters indicate the same or similar components, and the explanation thereof will be omitted.

### First Embodiment

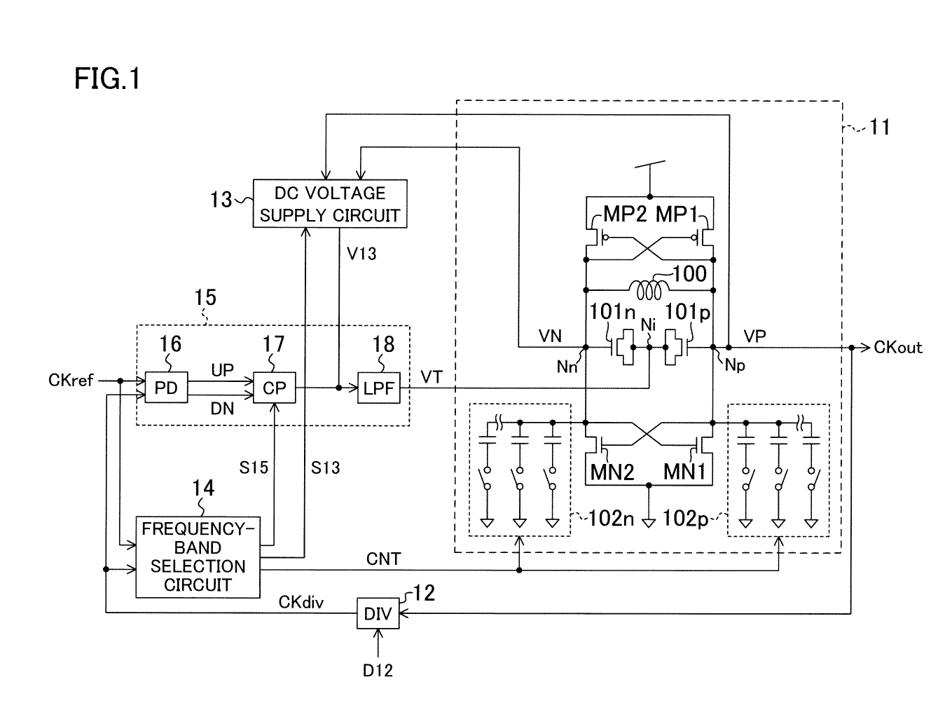

FIG. 1 illustrates an example configuration of a PLL frequency synthesizer according to the first embodiment. The PLL frequency synthesizer has a coarse-adjustment mode and a fine-adjustment mode, and includes a voltage-controlled oscillator (VCO) 11, a programmable frequency divider 12, a direct current (DC) voltage supply circuit 13, a frequency-band selection circuit 14, and an oscillation control circuit 15.

<VCO>

The VCO 11 includes an inductor 100, fine-adjustment capacitors 101p and 101n, coarse-adjustment capacitors 102p and 102n, pMOS transistors MP1 and MP2, and nMOS transistors MN1 and MN2.

The inductor 100 is coupled between an oscillation node Np and an oscillation node Nn. The fine-adjustment capacitor 101p is coupled between a control node Ni and the oscillation node Np, and the fine-adjustment capacitor 101n is coupled between the control node Ni and the oscillation node Nn. The capacitance value of the fine-adjustment capacitor 101p is continuously variable according to a voltage difference across the both ends of the fine-adjustment capacitor 101p (i.e., the voltage difference between the control node Ni and the oscillation node Np). Here, the fine-adjustment capacitor 101p has a capacitance characteristic such that as a differential voltage obtained by subtracting a control voltage VT at the control node Ni from an oscillation voltage VP at the oscillation node Np increases, the capacitance value increases. For example, the fine-adjustment capacitor 101p is formed by a MOS variable capacitor having a source and a drain both coupled to the control node Ni and a gate coupled to the oscillation node Np. The configuration of the fine-adjustment capacitor 101n is similar to that of the fine-adjustment capacitor 101p.

The coarse-adjustment capacitor 102p is coupled between the oscillation node Np and a ground node, and the coarse-adjustment capacitor 102n is coupled between the oscillation node Nn and the ground node. The capacitance value of the coarse-adjustment capacitor 102p is switchable in a stepwise fashion by a control signal CNT from the frequency-band selection circuit 14. For example, the coarse-adjustment capacitor 102p includes a plurality of fixed capacitors, and a plurality of switching elements which switch connection statuses of the plurality of fixed capacitors in response to the control signal CNT. The configuration of the coarse-adjustment capacitor 102n is similar to that of the coarse-adjustment capacitor 102p.

The sources of the pMOS transistors MP1 and MP2 are coupled to a power-source node; the drain of the pMOS transistor MP1 and the gate of the pMOS transistor MP2 are coupled to the oscillation node Np; and the gate of the pMOS transistor MP1 and the drain of the pMOS transistor MP2 are coupled to the oscillation node Nn. The sources of the nMOS transistors MN1 and MN2 are coupled to the ground node; the drain of the nMOS transistor MN1 and the gate of the nMOS transistor MN2 are coupled to the oscillation node Np; and the gate of the nMOS transistor MN1 and the drain of the nMOS transistor MN2 are coupled to the oscillation node Nn.

<Oscillation Frequency Band>

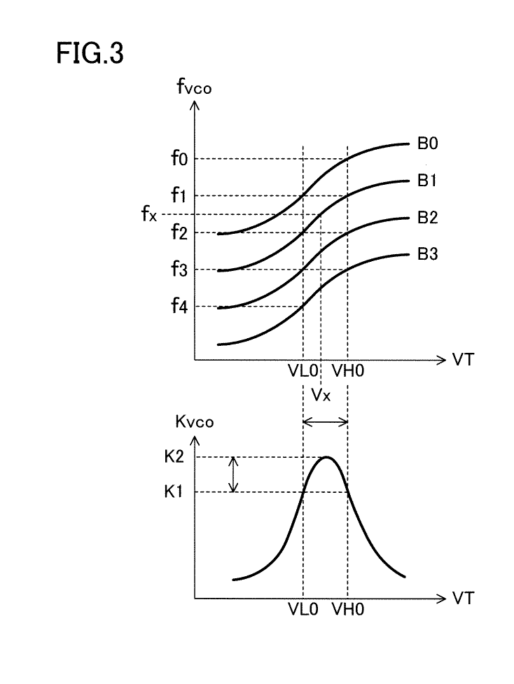

The VCO 11 generates an oscillation clock CKout having an oscillation frequency depending on the inductance value of the inductor 100 and on the capacitance values of the fine-adjustment capacitors 101p and 101n and the coarse-adjustment capacitors 102p and 102n. The oscillation frequency band of the VCO 11 is switched according to the capacitance value of the coarse-adjustment capacitors 102p and 102n. For example, as shown in FIG. 3, the VCO 11 has four oscillation frequency bands B0, B1, B2, and B3; and each increase of one step in the capacitance value of the coarse-adjustment capacitor 102p and 102n starting from a minimum value causes the oscillation frequency band of the VCO 11 to be switched sequentially in order of the oscillation frequency bands B0, B1, B2, and B3. The oscillation frequency in each oscillation frequency band continuously varies according to the capacitance value of the fine-adjustment capacitors 101p and 101n. For example, as shown in FIG. 3, the oscillation frequency fvco nonlinearly increases with an increase of the control voltage VT in each of the oscillation frequency bands B0, B1, B2, and B3.

In addition, in FIG. 3, when the control voltage VT varies over a range of voltage values VL0-VH0, the VCO gain Kvco of the VCO 11 varies in a range of gain values K1-K2. The VCO gain Kvco is equivalent to an amount of change of the oscillation frequency fvco per unit voltage change of the control voltage VT (i.e., a value obtained by differentiating the oscillation frequency fvco with respect to the control voltage VT). Note that, in order to reduce variation in characteristics (e.g., variation in a loop time constant) of a PLL frequency synthesizer, it is preferable that a variation range of the VCO gain Kvco be limited. Moreover, the oscillation frequency bands B0, B1, B2, and B3 are set (that is, a variation range of the capacitance value of the coarse-adjustment capacitors 102p and 102n is set) so that the oscillation frequency bands B0, B1, B2, and B3 do not overlap one another in the range of the voltage values VL0-VH0. Thus, the oscillation frequency bands B0, B1, B2, and B3 respectively correspond to a range of frequencies f0-f1, a range of frequencies f1-f2, a range of frequencies f2-f3, and a range of frequencies f3-f4.

<Programmable Frequency Divider>

Returning to FIG. 1, the programmable frequency divider 12 divides the frequency of the oscillation clock CKout according to a preset division ratio D12 to generate a divided clock CKdiv.

<DC Voltage Supply Circuit>

The DC voltage supply circuit 13 supplies a DC voltage V13 to the control node Ni, and changes the voltage value of the DC voltage V13 according to the DC value of the oscillation voltages VP and VN in the coarse-adjustment mode. Here, if the DC value of the oscillation voltages VP and VN is higher than a predetermined reference value (e.g., half the supply voltage), the DC voltage supply circuit 13 increases the voltage value of the DC voltage V13 according to a difference between the DC value of the oscillation voltages VP and VN and the reference value; and if the DC value of the oscillation voltages VP and VN is lower than the reference value, the DC voltage supply circuit 13 decreases the voltage value of the DC voltage V13 according to the difference between the DC value of the oscillation voltages VP and VN and the reference value. In addition, the DC voltage supply circuit 13 stops supplying the DC voltage V13 in the fine-adjustment mode.

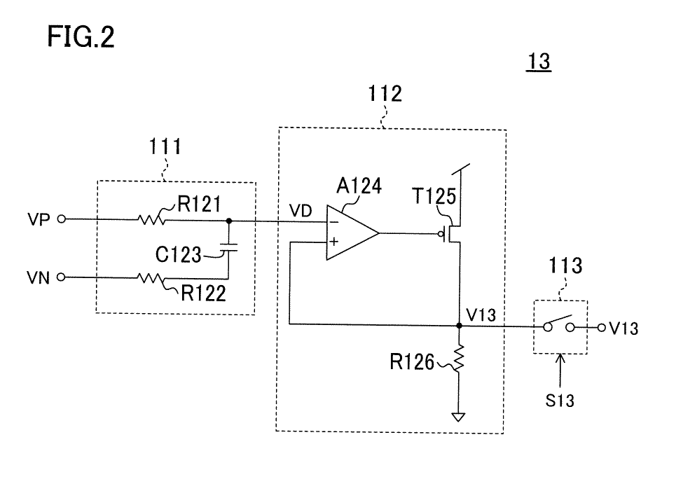

As shown in FIG. 2, for example, the DC voltage supply circuit 13 includes a voltage detection section 111, a voltage generation section 112, and an output switching section 113. The voltage detection section 111 detects the DC value VD of the oscillation voltages VP and VN by attenuating high-frequency components of the oscillation voltages VP and VN. The voltage detection section 111 may be a low-pass filter including resistive elements R121 and R122, and a capacitive element C123. The voltage generation section 112 generates the DC voltage V13 according to the DC value VD of the oscillation voltages VP and VN detected by the voltage detection section 111. Here, the voltage generation section 112 changes the voltage value of the DC voltage V13 so that the voltage value of the DC voltage V13 matches the DC value VD of the oscillation voltages VP and VN. The voltage generation section 112 may be a constant voltage circuit including an operational amplifier A124, a pMOS transistor T125, and a resistive element R126. The output switching section 113 is turned on and off in response to a control signal S13 from the frequency-band selection circuit 14. The output switching section 113 is set to an ON state in the coarse-adjustment mode, and is set to an OFF state in the fine-adjustment mode.

<Frequency-Band Selection Circuit>

Returning to FIG. 1, in the coarse-adjustment mode, the frequency-band selection circuit 14 switches the capacitance value of the coarse-adjustment capacitors 102p and 102n based on a frequency difference between a reference clock CKref and the divided clock CKdiv so that the oscillation frequency band of the VCO 11 is set to an oscillation frequency band corresponding to a target frequency (a frequency determined by the frequency of the reference clock CKref and the division ratio D12 of the programmable frequency divider 12).

<Oscillation Control Circuit>

In the fine-adjustment mode, the oscillation control circuit 15 increases or decreases the control voltage VT at the control node Ni according to a phase difference between the reference clock CKref and the divided clock CKdiv. In addition, in the coarse-adjustment mode, the oscillation control circuit 15 does not increase or decrease the control voltage VT. The oscillation control circuit 15 includes, for example, a phase-difference detector (PD) 16, a charge pump (CP) 17, and a low-pass filter (LPF) 18. The phase-difference detector 16 outputs an up signal UP when the phase of the divided clock CKdiv lags the phase of the reference clock CKref, and outputs a down signal DN when the phase of the divided clock CKdiv leads the phase of the reference clock CKref. The charge pump 17 increases an output voltage in response to the up signal UP, and decreases the output voltage in response to the down signal DN. The charge pump 17 is set to a high-impedance state by a control signal S15 from the frequency-band selection circuit 14. The low-pass filter 18 attenuates high-frequency components of the output voltage of the charge pump 17, and supplies the obtained output voltage to the control node Ni. Note that the DC voltage V13 may be supplied to the control node Ni through the low pass filter 18, or may be directly supplied to the control node Ni.

<Basic Operation>

Next, referring to FIG. 3, a basic operation by the PLL frequency synthesizer shown in FIG. 1 will be described. After selecting the oscillation frequency band B1 corresponding to a target frequency fx from the oscillation frequency bands B0, B1, B2, and B3 in the coarse-adjustment mode, the PLL frequency synthesizer transitions to the fine-adjustment mode, then controls the oscillation frequency of the oscillation clock CKout according to a phase difference between the reference clock CKref and the divided clock CKdiv in the fine-adjustment mode.

First, the frequency-band selection circuit 14 sets the output switching section 113 of the DC voltage supply circuit 13 to an ON state using the control signal S13, and sets the charge pump 17 to a high-impedance state using the control signal S15. The DC voltage supply circuit 13 supplies the DC voltage V13 having the voltage value VH0. This causes the voltage value of the control voltage VT to be set to the voltage value VH0. In addition, while switching the capacitance value of the coarse-adjustment capacitors 102p and 102n (i.e., while switching the oscillation frequency band of the VCO 11), the frequency-band selection circuit 14 compares the frequency of the reference clock CKref with the frequency of the divided clock CKdiv. For example, the frequency-band selection circuit 14 increases the oscillation frequency of the VCO 11 one step at a time by switching the oscillation frequency band sequentially in order of the oscillation frequency bands B3, B2, B1, and B0. In this case, since the voltage value of the control voltage VT is set to the voltage value VH0, the oscillation frequency of the oscillation clock CKout increases sequentially in order of the frequencies f3, f2, f1, and f0. Here, when the oscillation frequency band of the VCO 11 is switched from the oscillation frequency band B2 to the oscillation frequency band B1, the frequency of the divided clock CKdiv exceeds the frequency of the reference clock CKref. That is, the relative magnitude relationship between the frequencies of the divided clock CKdiv and the reference clock CKref is reversed. Then, the frequency-band selection circuit 14 determines that the oscillation frequency band of the VCO 11 is the oscillation frequency band B1. In this way, the oscillation frequency band of the VCO 11 is set to the oscillation frequency band B1 corresponding to the target frequency fx.

Next, the frequency-band selection circuit 14 sets the output switching section 113 of the DC voltage supply circuit 13 from an ON state to an OFF state using the control signal S13, and resets the state of the charge pump 17 back from the high-impedance state using the control signal S15. The oscillation control circuit 15 increases or decreases the control voltage VT according to a phase difference between the reference clock CKref and the divided clock CKdiv. This causes the voltage value of the control voltage VT to be set to a voltage value Vx, and the oscillation frequency of the oscillation clock CKout to be set to the target frequency fx.

<Variation of DC Value of Oscillation Voltages>

Next, a case will be described in which the DC value of the oscillation voltages VP and VN varies from the reference value due to manufacturing variation, supply voltage variation, temperature change, etc.

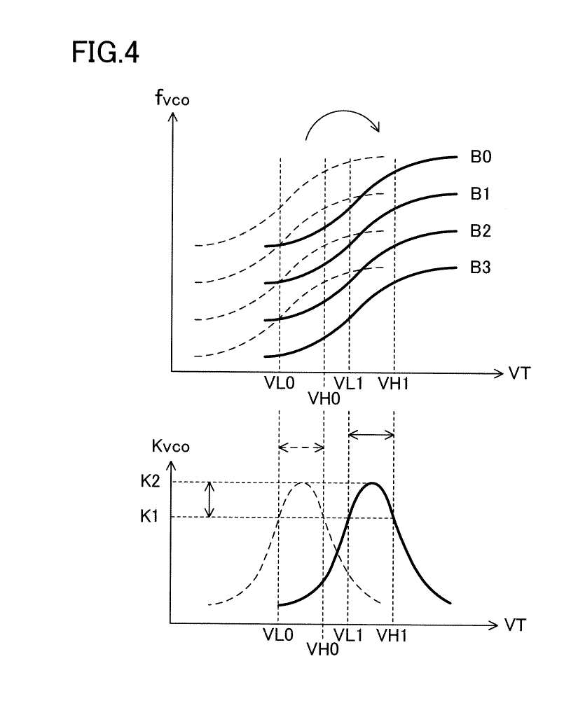

If the DC value of the oscillation voltages VP and VN exceeds the reference value, then as shown in FIG. 4, the f-V characteristic curve illustrating the f-V characteristic (relationship between the control voltage VT and the oscillation frequency fvco) of the VCO 11 shifts to the right (direction along which the control voltage VT increases) according to an increased amount of the DC value of the oscillation voltages VP and VN. In association with this, the gain characteristic curve illustrating the VCO gain Kvco of the VCO 11 also shifts to the right. Accordingly, the range of the control voltage VT in which the VCO gain Kvco varies over the range of the gain values K1-K2 shifts from the range of the voltage values VL0-VH0 to a range of voltage values VL1-VH1. In this regard, the DC voltage supply circuit 13 increases the voltage value of the DC voltage V13 according to the increased amount of the DC value of the oscillation voltages VP and VN. This causes the voltage value of the DC voltage V13 to shift from the voltage value VH0 to the voltage value VH1. As a result, the control voltage VT can be changed in the range of the voltage values VL1-VH1 in the fine-adjustment mode; therefore, the variation range of the VCO gain Kvco can be maintained in the range of the gain values K1-K2.

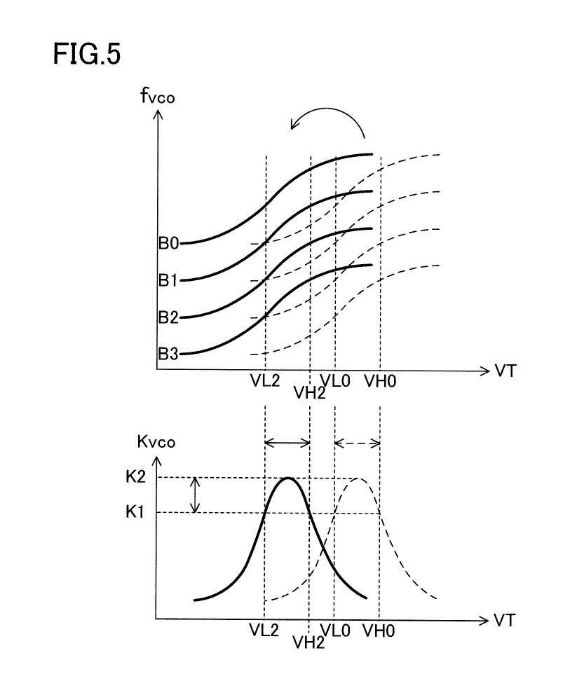

Meanwhile, if the DC value of the oscillation voltages VP and VN falls below the reference value, then as shown in FIG. 5, the f-V characteristic curve shifts to the left (direction along which the control voltage VT decreases) according to a decreased amount of the DC value of the oscillation voltages VP and VN. In association with this, the gain characteristic curve also shifts to the left, and thus the range of the control voltage VT in which the VCO gain Kvco varies over the range of the gain values K1-K2 shifts from the range of the voltage values VL0-VH0 to a range of voltage values VL2-VH2. In this regard, the DC voltage supply circuit 13 decreases the voltage value of the DC voltage V13 according to the decreased amount of the DC value of the oscillation voltages VP and VN. This causes the voltage value of the DC voltage V13 to shift from the voltage value VH0 to the voltage value VH2. Thus, the control voltage VT can be changed in the range of the voltage values VL2-VH2 in the fine-adjustment mode; therefore, the variation range of the VCO gain Kvco can be maintained in the range of the gain values K1-K2.

As described above, by changing the voltage value of the DC voltage V13 according to an amount of variation of the DC value of the oscillation voltages VP and VN, variation in the gain characteristic of the VCO 11 can be reduced. This allows variation in characteristics (e.g., variation in a loop time constant) of the PLL frequency synthesizer to be reduced.

### Variation of First Embodiment

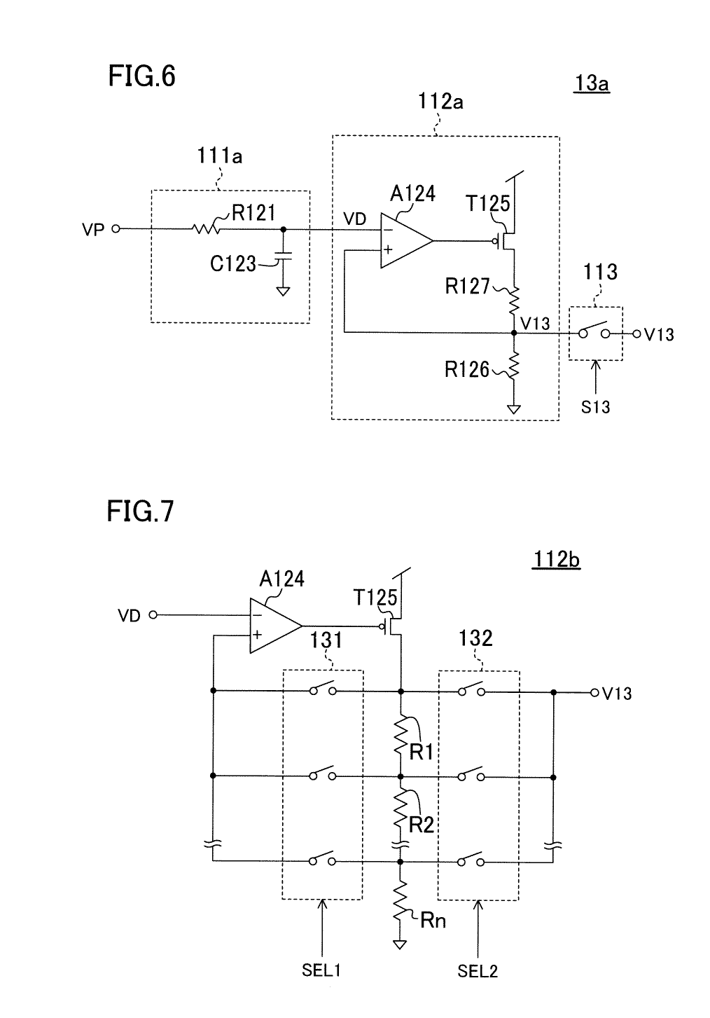

The DC voltage supply circuit 13 may change the voltage value of the DC voltage V13 according to the DC value of either the oscillation voltage VP or VN, instead of that of both the oscillation voltages VP and VN. In addition, the DC voltage supply circuit 13 may change the voltage value of the DC voltage V13 so that the voltage value of the DC voltage V13 matches a voltage value obtained by adding a predetermined offset value to the DC value of the oscillation voltages VP and VN (or the DC value of either the oscillation voltage VP or VN). The PLL frequency synthesizer of FIG. 1 may include, for example, a DC voltage supply circuit 13a of FIG. 6 instead of the DC voltage supply circuit 13. In the DC voltage supply circuit 13a, a voltage detection section 111a detects the DC value VD of the oscillation voltage VP by attenuating high-frequency components of the oscillation voltage VP. For example, the voltage detection section 111a is a low-pass filter including a resistive element R121 and a capacitive element C123. The voltage generation section 112a generates the DC voltage V13 having a voltage value obtained by adding the offset value to the DC value VD of the oscillation voltage VP detected by the voltage detection section 111a. For example, the voltage generation section 112a is a constant voltage circuit including an operational amplifier A124, a pMOS transistor T125, and resistive elements R126 and R127. Thus, since the DC voltage V13 includes an offset value, the voltage value of the control voltage VT in the coarse-adjustment mode can be set to an arbitrary voltage value different from the DC value of the oscillation voltages VP and VN (e.g., the voltage value VL0). In addition, adjustment of the voltage value of the control voltage VT in the coarse-adjustment mode allows the variation range of the control voltage VT in the fine-adjustment mode to be adjusted, thereby allows the gain characteristic of the VCO 11 to be further improved.

Moreover, the offset value included in the DC voltage V13 may be variable. For example, the DC voltage supply circuits 13 and 13a shown respectively in FIGS. 2 and 6 may each include a voltage generation section 112b shown in FIG. 7 instead of the voltage generation section 112 or 112a. The voltage generation section 112b changes the voltage value of the DC voltage V13 so that the voltage value of the DC voltage V13 matches the voltage value obtained by adding the offset value to the DC value VD. In addition, the voltage generation section 112b changes the offset value in response to external control signals SEL1 and SEL2. The voltage generation section 112b includes, for example, n resistive elements R1, R2, . . . , Rn coupled in series and switching sections 131 and 132, instead of the resistive element R126 shown in FIG. 2. The switching section 131 couples one of the n resistive elements R1, R2, . . . , Rn to the non-inverting input of the operational amplifier A124 in response to the control signal SEL1, and the switching section 132 couples one of the n resistive elements R1, R2, . . . , Rn to the output switching section 113 in response to the control signal SEL2. Thus, by designing the offset value included in the DC voltage V13 as a variable, the voltage value of the control voltage VT in the coarse-adjustment mode and the variation range of the control voltage VT in the fine-adjustment mode can be arbitrarily set.

### Second Embodiment

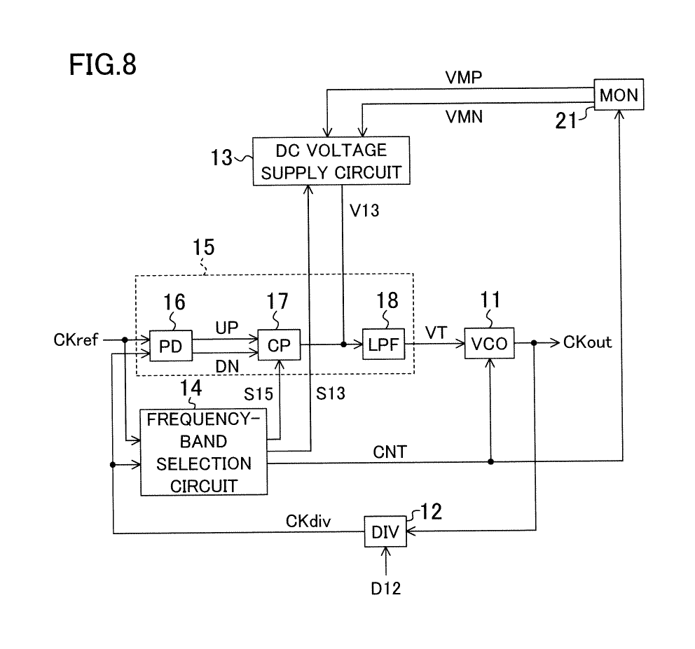

FIG. 8 illustrates an example configuration of a PLL frequency synthesizer according to the second embodiment. This PLL frequency synthesizer includes a monitor circuit 21, having a same configuration as that of the VCO 11, in addition to the components of the PLL frequency synthesizer shown in FIG. 1. The frequency-band selection circuit 14 switches the capacitance value of the coarse-adjustment capacitors 102p and 102n included in the VCO 11, and also switches the capacitance value of coarse-adjustment capacitors 102p and 102n included in the monitor circuit 21. Similarly to the VCO 11, the control voltage VT is applied to a control node Ni of the monitor circuit 21. The DC voltage supply circuit 13 receives monitor voltages VMP and VMN generated at oscillation nodes Np and Nn of the monitor circuit 21 instead of the oscillation voltages VP and VN, and changes the voltage value of the DC voltage V13 according to the DC value of the monitor voltages VMP and VMN.

Thus, supplying the DC voltage supply circuit 13 with the monitor voltages VMP and VMN of the monitor circuit 21, instead of the oscillation voltages VP and VN of the VCO 11, eliminates the necessity of coupling the DC voltage supply circuit 13 to the oscillation nodes Np and Nn of the VCO 11, thereby preventing noise from being added to the oscillation clock CKout.

### Variation of Second Embodiment

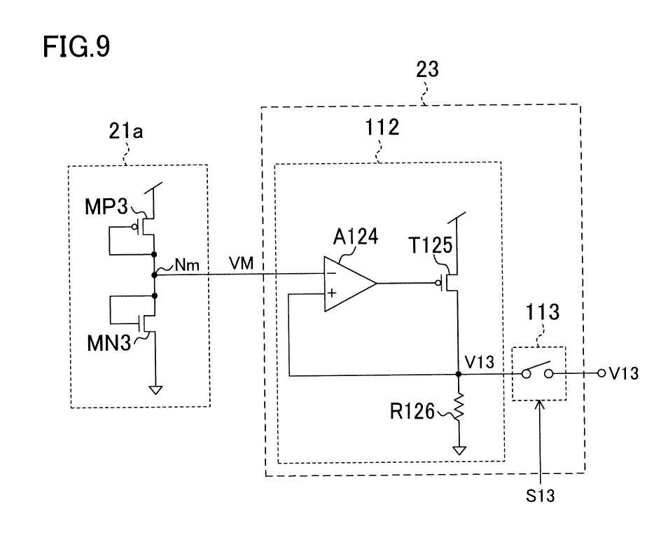

The PLL frequency synthesizer shown in FIG. 8 may include a monitor circuit 21a and a DC voltage supply circuit 23 shown in FIG. 9 instead of the monitor circuit 21 and the DC voltage supply circuit 13. The monitor circuit 21a includes a pMOS transistor MP3 and an nMOS transistor MN3. The source of the pMOS transistor MP3 is coupled to the power-source node, and the source of the nMOS transistor MN3 is coupled to the ground node; the drain and the gate of the pMOS transistor MP3 and the drain and the gate of the nMOS transistor MN3 are coupled to a monitor node Nm. That is, the pMOS transistor MP3 and the nMOS transistor MN3 respectively correspond to the pMOS transistor MP1 and the nMOS transistor MN1 of the VCO 11. This configuration allows a voltage characteristic similar to that at the oscillation node Np of the VCO 11 to be produced at the monitor node Nm. Accordingly, a monitor voltage VM, corresponding to the DC value of the oscillation voltage VP at the oscillation node Np of the VCO 11, is generated at the monitor node Nm.

The DC voltage supply circuit 23 receives the monitor voltage VM generated by the monitor circuit 21a instead of the oscillation voltages VP and VN, and changes the voltage value of the DC voltage V13 according to the monitor voltage VM. Here, since the DC value of the monitor voltage VM does not need to be detected, the DC voltage supply circuit 23 does not need to include the voltage detection section 111 or 111a. In addition, the DC voltage supply circuit 23 may include, instead of the voltage generation section 112, the voltage generation section 112a shown in FIG. 6 or the voltage generation section 112b shown in FIG. 7.

Thus, by producing a similar DC value to that of the oscillation voltages VP and VN of the VCO 11 by the simplified monitor circuit, noise is prevented from being added to the oscillation clock CKout, and the circuit area can be further reduced compared to the monitor circuit 21 shown in FIG. 8.

### Third Embodiment

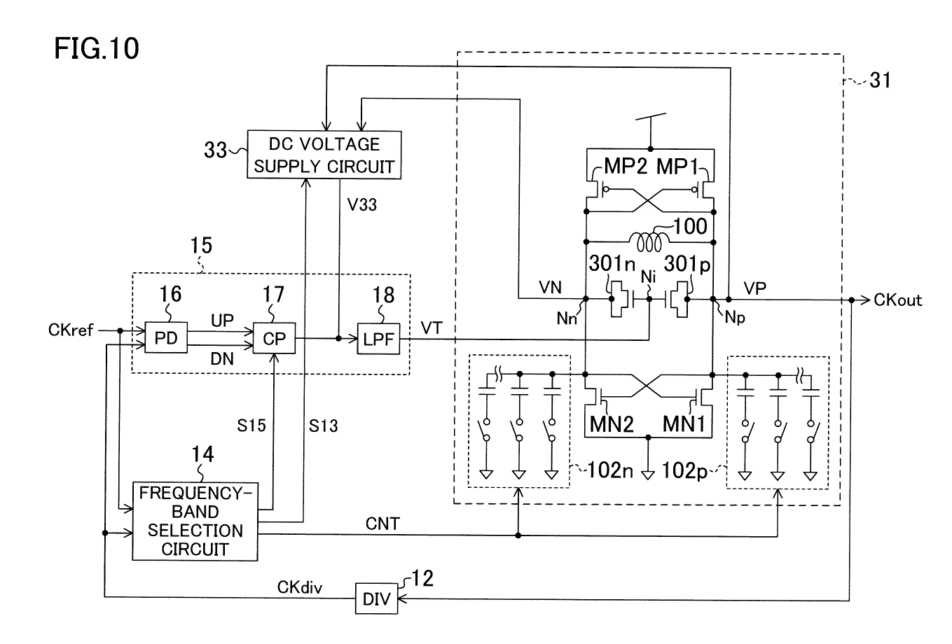

FIG. 10 illustrates an example configuration of a PLL frequency synthesizer according to the third embodiment. This PLL frequency synthesizer includes a VCO 31 and a DC voltage supply circuit 33 instead of the VCO 11 and the DC voltage supply circuit 13 shown in FIG. 1.

<VCO>

The VCO 31 includes fine-adjustment capacitors 301p and 301n instead of the fine-adjustment capacitors 101p and 101n shown in FIG. 1. The other part of configuration is similar to that of the VCO 11 shown in FIG. 1. The fine-adjustment capacitor 301p has a capacity characteristic such that as a differential voltage obtained by subtracting the oscillation voltage VP from the control voltage VT increases, the capacitance value increases. For example, the fine-adjustment capacitor 301p is formed by a MOS variable capacitor having a source and a drain both coupled to the oscillation node Np and a gate coupled to the control node Ni. The configuration of the fine-adjustment capacitor 301n is similar to that of the fine-adjustment capacitor 301p.

<DC Voltage Supply Circuit>

The DC voltage supply circuit 33 supplies a DC voltage V33 to the control node Ni in the coarse-adjustment mode. Here, if the DC value of the oscillation voltages VP and VN is higher than a predetermined reference value (e.g., half the supply voltage), the DC voltage supply circuit 33 decreases the voltage value of the DC voltage V33 according to a difference between the DC value of the oscillation voltages VP and VN and the reference value; and if the DC value of the oscillation voltages VP and VN is lower than the reference value, the DC voltage supply circuit 33 increases the voltage value of the DC voltage V33 according to a difference between the DC value of the oscillation voltages VP and VN and the reference value. In addition, the DC voltage supply circuit 33 stops supplying the DC voltage V33 in the fine-adjustment mode.

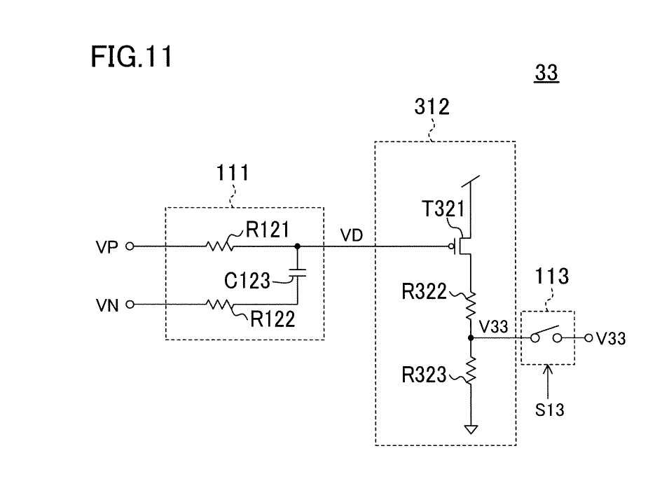

For example, as shown in FIG. 11, the DC voltage supply circuit 33 includes a voltage detection section 111, a voltage generation section 312, and an output switching section 113. If the DC value of the oscillation voltages VP and VN is higher than the reference value, then the voltage generation section 312 changes the voltage value of the DC voltage V33 so that the voltage value of the DC voltage V33 matches a voltage value obtained by subtracting a difference value (difference between the DC value of the oscillation voltages VP and VN and the reference value) from a predetermined value (e.g., the reference value); and if the DC value of the oscillation voltages VP and VN is lower than the reference value, then the voltage generation section 312 changes the voltage value of the DC voltage V33 so that the voltage value of the DC voltage V33 matches a voltage value obtained by adding the difference value to the predetermined value. The voltage generation section 312 may include a pMOS transistor T321 and resistive elements R322 and R323.

<Phase-Difference Detector>

Here, the phase-difference detector 16 outputs a down signal DN when the phase of the divided clock CKdiv lags the phase of the reference clock CKref, and outputs an up signal UP when the phase of the divided clock CKdiv leads the phase of the reference clock CKref.

<Variation of DC Value of Oscillation Voltages>

Next, a case will be described in which the DC value of the oscillation voltages VP and VN varies from the reference value due to manufacturing variation, supply voltage variation, temperature change, etc.

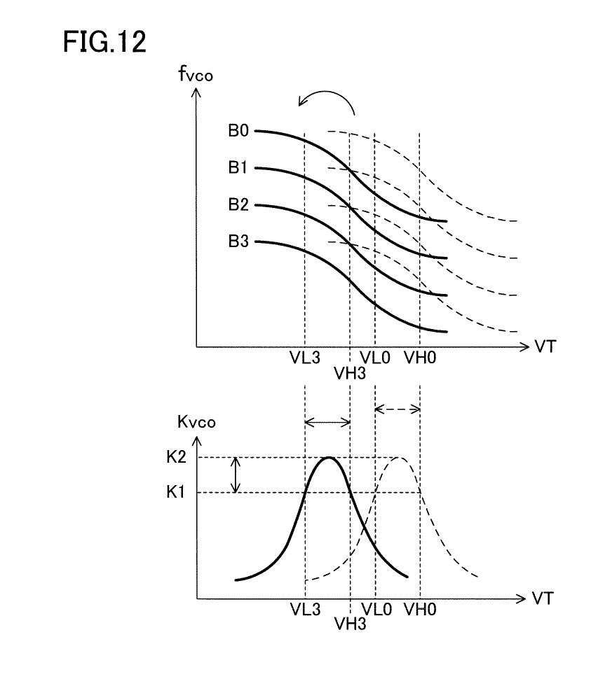

If the DC value of the oscillation voltages VP and VN exceeds the reference value, then as shown in FIG. 12, the f-V characteristic curve shifts to the left (direction along which the control voltage VT decreases) according to an increased amount of the DC value of the oscillation voltages VP and VN. In association with this, the gain characteristic curve also shifts to the left. Accordingly, the range of the control voltage VT in which the VCO gain Kvco varies over the range of the gain values K1-K2 shifts from the range of the voltage values VL0-VH0 to a range of voltage values VL3-VH3. In this regard, the DC voltage supply circuit 33 decreases the voltage value of the DC voltage V33 according to the increased amount of the DC value of the oscillation voltages VP and VN. This causes the voltage value of the DC voltage V33 to shift from the voltage value VH0 to the voltage value VH3. Thus, the control voltage VT can be changed in the range of the voltage values VL3-VH3 in the fine-adjustment mode; therefore, the variation range of the VCO gain Kvco can be maintained in the range of the gain values K1-K2.

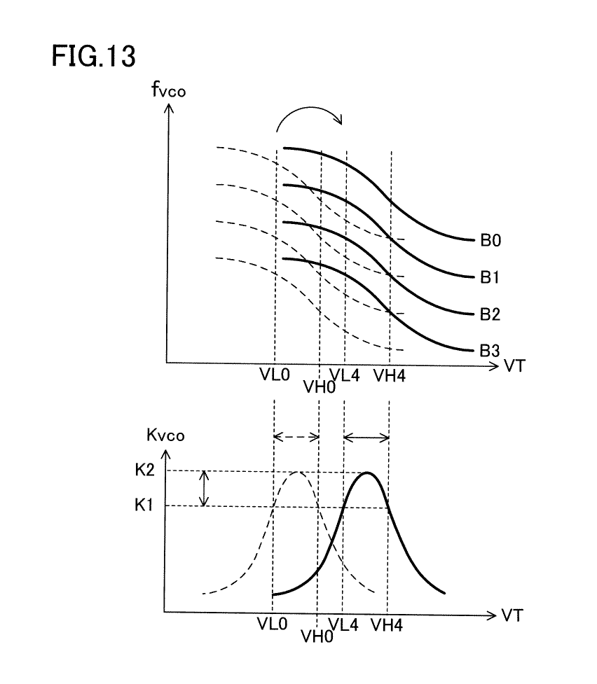

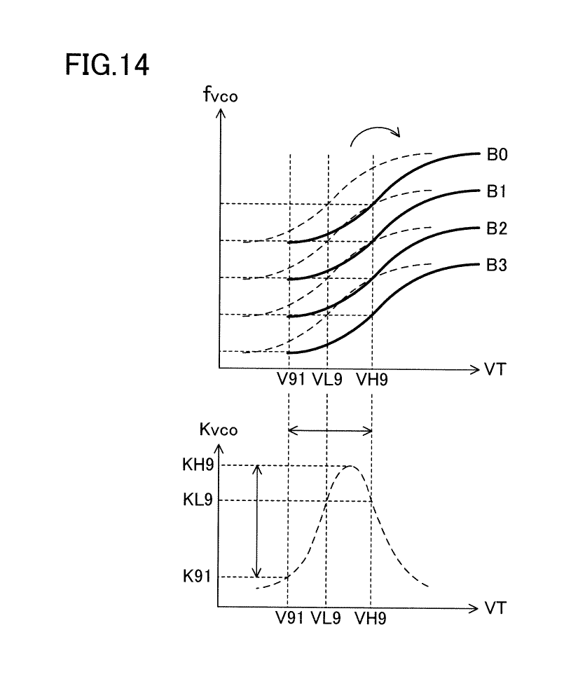

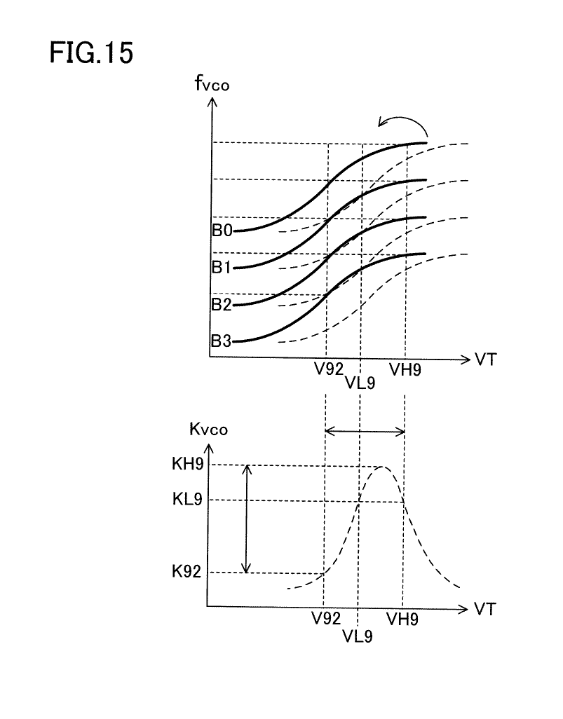

Meanwhile, if the DC value of the oscillation voltages VP and VN falls below the reference value, then as shown in FIG. 13, the f-V characteristic curve shifts to the right (direction along which the control voltage VT increases) according to a decreased amount of the DC value of the oscillation voltages VP and VN. In association with this, the gain characteristic curve also shifts to the right. Accordingly, the range of the control voltage VT in which the VCO gain Kvco varies over the range of the gain values K1-K2 shifts from the range of the voltage values VL0-VH0 to a range of voltage values VL4-VH4. In this regard, the DC voltage supply circuit 33 increases the voltage value of the DC voltage V33 according to the decreased amount of the DC value of the oscillation voltages VP and VN. This causes the voltage value of the DC voltage V33 to shift from the voltage value VH0 to the voltage value VH4. Thus, the control voltage VT can be changed in the range of the voltage values VL4-VH4 in the fine-adjustment mode; therefore, the variation range of the VCO gain Kvco can be maintained in the range of the gain values K1-K2.

As described above, by changing the voltage value of the DC voltage V33 according to an amount of variation of the DC value of the oscillation voltages VP and VN, variation in the gain characteristic of the VCO 31 can be reduced. This allows variation in characteristics of the PLL frequency synthesizer to be reduced.

Note that, similarly to the variation of the first embodiment, the DC voltage V33 may include an offset value. Moreover, the offset value included in the DC voltage V33 may be variable.

Similarly to the second embodiment, the PLL frequency synthesizer shown in FIG. 10 may further include a monitor circuit having a same configuration as that of the VCO 31. In such a case, the DC voltage supply circuit 33 may change the voltage value of the DC voltage V33 according to the DC value of the monitor voltages respectively generated at oscillation nodes Np and Nn of the monitor circuit. Alternatively, similarly to the variation of the second embodiment, the PLL frequency synthesizer shown in FIG. 10 may further include the monitor circuit 21a shown in FIG. 9. In such a case, the DC voltage supply circuit 33 does not need to include the voltage detection section 111.

### Other Embodiments

In each of the foregoing embodiments, the fine-adjustment capacitors 101p, 101n, 301p, and 301n may be MOS variable capacitors or varactor diodes. The configurations of the VCOs 11 and 31 are not limited to those (of differential design) shown in FIGS. 1 and 10, and may be other configurations. Each of the VCOs may be one which includes at least one inductor, at least one fine-adjustment capacitor, and at least one coarse-adjustment capacitor.

Moreover, in order to set the oscillation frequency band of a VCO to the oscillation frequency band corresponding to a target frequency, the frequency-band selection circuit 14 may decrease the oscillation frequency of the VCO one step at a time by switching the oscillation frequency band sequentially in order of the oscillation frequency bands B0, B1, B2, and B3, or may switch the oscillation frequency of the VCO in another manner. In the coarse-adjustment mode, the voltage value of the control voltage VT (i.e., the voltage value of the DC voltage) may be set to the voltage value VL0 or to any voltage value within the range of the voltage values VL0-VH0.

As described above, since the described PLL frequency synthesizers can reduce variation in the gain characteristics of the VCOs, these PLL frequency synthesizers are useful as clock generation circuits etc. for generating local signals necessary for transmitting and receiving radio waves.

It is to be understood that the foregoing embodiments are illustrative in nature, and are not intended to limit the scope of the invention, application of the invention, or use of the invention.

What is claimed is:

1. A PLL frequency synthesizer having a coarse-adjustment mode and a fine-adjustment mode, comprising:
a voltage-controlled oscillator (VCO), having an inductor, a fine-adjustment capacitor, coupled between a control node and an oscillation node, whose capacitance value is continuously variable according to a voltage difference between the control node and the oscillation node, and a coarse-adjustment capacitor whose capacitance value can be switched in a stepwise fashion, the VCO being configured to generate an oscillation clock having an oscillation frequency depending on an inductance value of the inductor and on capacitance values of the fine-adjustment capacitor and the coarse-adjustment capacitor;
a frequency divider configured to divide the frequency of the oscillation clock to generate a divided clock;
a direct current (DC) voltage supply circuit configured to, in the coarse-adjustment mode, supply a DC voltage to the control node and change a voltage value of the DC voltage according to a DC value of an oscillation voltage at the oscillation node, and in the fine-adjustment mode, stop supplying the DC voltage;
a frequency-band selection circuit configured to, in the coarse-adjustment mode, switch the capacitance value of the coarse-adjustment capacitor based on a frequency difference between a reference clock and the divided clock so that an oscillation frequency band of the VCO is set to an oscillation frequency band corresponding to a target frequency determined by a frequency of the reference clock and a division ratio of the frequency divider; and
an oscillation control circuit configured to, in the fine-adjustment mode, increase or decrease a control voltage at the control node according to a phase difference between the reference clock and the divided clock.

2. The PLL frequency synthesizer of claim 1, wherein
the fine-adjustment capacitor has a capacitance characteristic such that as a differential voltage obtained by subtracting the control voltage from the oscillation voltage increases, the capacitance value increases, and
the DC voltage supply circuit, if the DC value of the oscillation voltage is higher than a predetermined reference value, increases the voltage value of the DC voltage according to a difference between the DC value of the oscillation voltage and the reference value, and if the DC value of the oscillation voltage is lower than the reference value, decreases the voltage value of the DC voltage according to the difference between the DC value of the oscillation voltage and the reference value.

3. The PLL frequency synthesizer of claim 2, wherein
the DC voltage supply circuit changes the voltage value of the DC voltage so that the voltage value of the DC voltage matches the DC value of the oscillation voltage.

4. The PLL frequency synthesizer of claim 2, wherein
the DC voltage supply circuit changes the voltage value of the DC voltage so that the voltage value of the DC voltage matches a voltage value obtained by adding a predetermined offset value to the DC value of the oscillation voltage.

5. The PLL frequency synthesizer of claim 4, wherein
the offset value is variable.

6. The PLL frequency synthesizer of claim 1, wherein
the fine-adjustment capacitor has a capacitance characteristic such that as a differential voltage obtained by subtracting the oscillation voltage from the control voltage increases, the capacitance value increases, and
the DC voltage supply circuit, if the DC value of the oscillation voltage is higher than a predetermined reference value, decreases the voltage value of the DC voltage according to a difference between the DC value of the oscillation voltage and the reference value, and if the DC value of the oscillation voltage is lower than the reference value, increases the voltage value of the DC voltage according to the difference between the DC value of the oscillation voltage and the reference value.

7. The PLL frequency synthesizer of claim 1, further comprising:
a monitor circuit having a same configuration as that of the VCO, wherein
the DC voltage supply circuit receives a monitor voltage generated at an oscillation node of the monitor circuit, and changes the voltage value of the DC voltage according to a DC value of the monitor voltage.

8. The PLL frequency synthesizer of claim 1, further comprising:
a monitor circuit configured to produce a similar voltage characteristic to that at the oscillation node of the VCO, and generates a monitor voltage corresponding to the DC value of the oscillation voltage based on the voltage characteristic,
wherein
the DC voltage supply circuit receives a monitor voltage generated by the monitor circuit, and changes the voltage value of the DC voltage according to the monitor voltage.
